(19) United States
(12) Patent Application Publication
(10) Pub. No.: US 2020/0035629 A1
(43) Pub. Date: Jan. 30, 2020

(54) PACKAGED SEMICONDUCTOR DEVICE AND METHOD FOR PREPARING THE SAME

(71) Applicant: NANYA TECHNOLOGY CORPORATION, New Tapei City (TW)

(72) Inventor: MAO-YING WANG, NEW TAIPEI CITY (TW)

(21) Appl. No.: 16/046,100

(22) Filed: Jul. 26, 2018

(51) Int. Cl. H01L 23/00; H01L 21/66

(52) U.S. Cl. CPC H01L 24/05; H01L 2224/24226; H01L 22/14; H01L 2224/0236; H01L 2224/02381; H01L 2224/05569; H01L 2224/05556; H01L 2224/024; H01L 2924/07025; H01L 2224/02311; H01L 2224/05147; H01L 2224/05644; H01L 2224/05655; H01L 2224/02215; H01L 2224/02206; H01L 2224/05624; H01L 22/32; H01L 2224/24011; H01L 2224/24105; H01L 2224/24146; H01L 24/24

(57) ABSTRACT

The present disclosure provides a packaged semiconductor device and a method for preparing the same. The packaged semiconductor device includes a chip having a conductive pad; a first insulating layer disposed on the chip; a second insulating layer disposed on the first insulating layer; a conductive film disposed on the second insulating layer, a redistribution layer disposed on the conductive film; a probe pad disposed on the redistribution layer; and a third insulating, layer disposed on the redistribution layer and the second insulating layer, wherein the third insulating layer covers a portion of the probe pad, and there is no undercut at a region between the redistribution layer and the probe pad. The size of the probe pad is not limited by the undercut, as the size of the probe pad needs to be reduced in order to meet the requirement of continuous minimization of chip size.

### TECHNICAL FIELD

The present disclosure relates to a packaged semiconductor device and a method for preparing the same.

### DISCUSSION OF THE BACKGROUND

Semiconductor components are important for many modern lo applications. With the development of electronic technology, the size of semiconductor components is getting smaller, and devices provide more powerful functions with more integrated circuits. As semiconductor components become more sophisticated and their manufacturing methods become increasingly complex, the testing is before shipment becomes quite important. In general, a bonding pad is arranged on the packaged semiconductor device and probe pads, the bonding pads are used for wiring or bonding with other semiconductor components, and the probe pads are used for testing purposes.

This Discussion of the Background section is for background information only. The statements in this Discussion of the Background are not an admission that the subject matter disclosed in this section constitutes a prior art to the present disclosure, and no part of this section may be used as an admission that any part of this application, including this Discussion of the Background section, constitutes prior art to the present disclosure.

### SUMMARY

The present disclosure provides a packaged semiconductor device including a chip having a conductive pad; a first insulating layer disposed on the chip; a second insulating layer disposed on the first insulating layer; a conductive film disposed on the second insulating layer, wherein the conductive film penetrates the second insulating layer and contacts the conductive pad; a redistribution layer disposed on the conductive film; a probe pad disposed on the redistribution layer; and a third insulating layer disposed on the redistribution layer and the second insulating layer; wherein the third insulating layer covers a portion of the probe pad, and there is no undercut at a region between the redistribution layer and the probe pad.

In some embodiments, the packaged semiconductor device further comprises: a substrate, wherein the chip is disposed on the substrate; a first wiring layer disposed on the substrate; and a fourth insulating layer disposed on the third insulating layer and the first wiring layer; wherein a first conductive pillar penetrates the fourth insulating layer and contact the first wiring layer.

In some embodiments, the packaged semiconductor device further comprises: a substrate, wherein the chip is disposed on the substrate; a fourth insulating layer disposed on the third insulating layer and the bonding pad; a second wiring layer disposed on the fourth insulating layer; and a first conductive pillar penetrating the fourth insulating layer and contacting the bonding pad.

In some embodiments, the packaged semiconductor device further comprises a protective layer disposed between the first insulating layer and the chip.

In some embodiments, the probe pad comprises a metal block and a metal protective layer.

In some embodiments, the metal block is a copper block, and the metal protective layer is a nickel-gold layer.

In some embodiments, the conductive film comprises a protrusion protruding towards the chip.

In some embodiments, the material of the first insulating layer, the second insulating layer, and the third insulating layer comprises polyimide.

In some embodiments, the material of the redistribution layer is copper.

In some embodiments, the material of the conductive pad is aluminum.

In some embodiments, the packaged semiconductor device is further comprises a die-bonding film, wherein the die-bonding film covers the third insulating layer.

The present disclosure also provides a method for preparing a packaged semiconductor device. The method includes providing a chip having a conductive pad; forming a first insulating layer on the chip, wherein the first insulating layer includes a first opening, and the first opening exposes a portion of the conductive pad; forming a second insulating layer on the first insulating layer; forming a conductive film on the second insulating layer and the conductive pad; forming a first patterned mask on the second insulating layer, wherein the first patterned mask defines a first region exposing a portion of the conductive film; forming a redistribution layer in the first region; forming a second patterned mask on the redistribution layer, wherein the second patterned mask defines a second region exposing a portion of the redistribution layer; forming a probe pad in the second region; and forming a third insulating layer on the redistribution layer and the second insulating layer, wherein the third insulating layer includes a second opening, and the second opening exposes a portion of the probe pad.

In some embodiments, the method further comprises: mounting, the chip on a substrate having a first wiring layer thereon; forming a fourth insulating layer covering the first wiring layer and the third insulating layer; forming a metal layer covering the fourth insulating layer; forming a third opening and a fourth opening in the fourth insulating layer and the metal layer, wherein the third opening exposes a portion of the redistribution layer, and the fourth opening exposes a portion of the first wiring layer; forming a second wiring layer having a first conductive pillar and a second conductive pillar, wherein the first conductive pillar is in contact with the redistribution layer, and the second conductive pillar is in contact with the first wiring layer.

In some embodiments, the third opening and the fourth opening are formed by laser drilling.

In some embodiments, the forming of the probe pad comprises forming a nickel-gold layer.

In some embodiments, the material of the first insulating layer, the second insulating layer, and the third insulating layer comprises polyimide.

In some embodiments, the material of the redistribution layer is copper.

In some embodiments, the material of the conductive pad is aluminum.

In some embodiments, the method further comprises: attaching a die-bonding film to the third insulating layer.

In some embodiments, the method further comprises: removing the second patterned mask, wherein there is no undercut at a region between the redistribution layer and the probe pad.

The foregoing has outlined rather broadly the features and o technical advantages of the present disclosure in order that the detailed description of the disclosure that follows may be better understood. Additional features and technical advantages of the disclosure are described hereinafter, and form the subject of the claims of the disclosure. It should be appreciated by those skilled in the art that the concepts and specific embodiments disclosed may be utilized as a basis for modifying or designing other structures, or processes, for carrying out the purposes of the present disclosure. It should also be realized by those skilled in the art that such equivalent constructions do not depart from the spirit or scope of the disclosure as set forth in the appended claims.

### BRIEF DESCRIPTION OF THE DRAWINGS

A more complete understanding of the present disclosure may be derived by referring to the detailed description and claims. The disclosure should be understood to be connected to the figures' reference numbers, which refer to similar elements throughout the description.

FIG. 1 is a schematic diagram showing a comparative packaged semiconductor device.

FIG. 2 is a schematic diagram showing a packaged semiconductor device in accordance with some embodiments of the present disclosure.

FIG. 3 is a schematic diagram showing a packaged semiconductor device in accordance with some embodiments of the present disclosure.

FIG. 4A to FIG. 4L illustrate a method of manufacturing the packaged semiconductor device in FIG. 2 in accordance with some embodiments of the present disclosure.

FIG. 5A to FIG. 5D illustrate a manufacturing process for a packaged semiconductor device in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless is the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

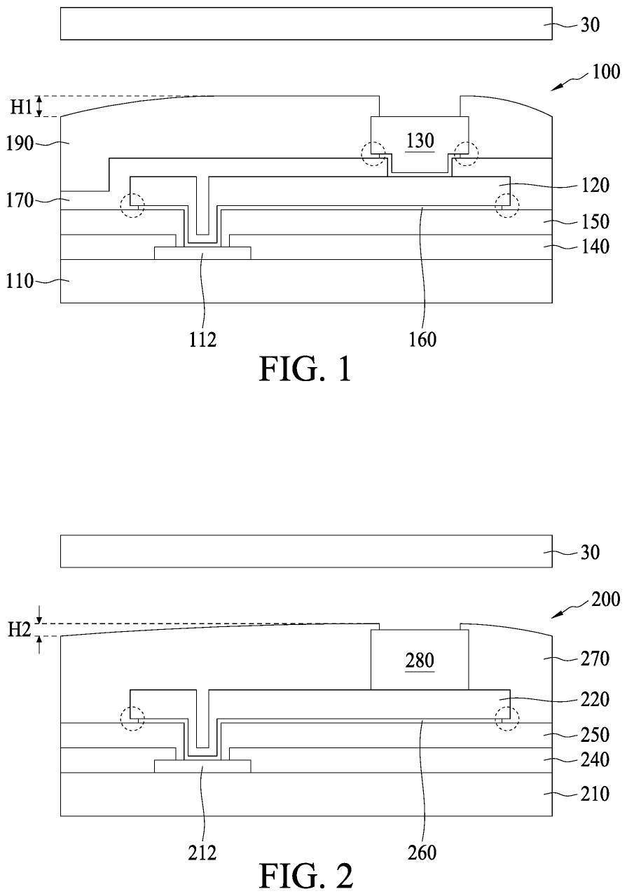

FIG. 1 is a schematic diagram showing a comparative packaged semiconductor device 100. The packaged semiconductor device 100 includes a wafer 110 having integrated circuit chips, a conductive pad 112, a redistribution layer 120, a probe pad 130, a first insulating layer 140, a second insulating layer 150, a conductive film 160, a third insulating layer 170, and a fourth insulating layer 190 disposed on the wafer 110, wherein the probe pad 130 is electrically connected to the conductive pad 112 via the redistribution layer 120.

Please note the regions indicated by the dashed circles in FIG. 1, which are regions where an undercut phenomenon is likely to occur. In detail, the undercut phenomenon tends to occur at the region between the redistribution layer 120 and the second insulating layer 150 and at the region between the probe pad 130 and the third insulating layer 170. The size of the probe pad 230 is limited by the undercut; therefore, reducing the occurrence of the undercut phenomenon is worthy of consideration by those with ordinary knowledge in the field, as the required size of the chip continues to get smaller.

FIG. 2 is a schematic diagram showing a packaged semiconductor device 200 in accordance with some embodiments of the present disclosure. In some embodiments, the packaged semiconductor device 200 comprises a wafer 210 having integrated circuit chips, a first insulating layer 240, a second insulating layer 250, a conductive film 260, a redistribution layer 220, a third insulating layer 270, and a probe pad 280. In some embodiments, the packaged semiconductor device 200 further comprises at least one conductive pad 212 disposed on a surface of the wafer 210.

In some embodiments, the first insulating layer 240 is disposed on the wafer 210, and at least a portion of the conductive pad 212 is not covered by the first insulating layer 240. In some embodiments, the protective layer 205 covers the sidewall and a portion of the top surface of the conductive pad 212. The second insulating layer 250 is disposed on the first insulating layer 240. The conductive film 260 is disposed on the second insulating layer 250 and the conductive pad 212. The redistribution layer 220 is disposed on the conductive film 260. The third insulating layer 270 is disposed on the redistribution layer 220 and the second insulating layer 250, wherein a portion of the probe pad 280 is not covered by the third insulating layer 270.

In comparing FIG. 1 and FIG. 2, it can be seen that, in the embodiment shown in FIG. 1, there are four regions (indicated by dashed circles) where the undercut phenomenon is likely to occur in the packaged semiconductor device 100, whereas in the embodiment shown in FIG. 2 there are only two regions (indicated by dashed circles) where the undercut phenomenon is likely to occur in the packaged semiconductor device 200. Therefore, the packaged semiconductor device 200 of the present disclosure is less prone to the occurrence of the undercut phenomenon, as compared to the packaged semiconductor device 100. In addition, there is no undercut at the bottom of the probe pad 280 in FIG. 2, and the size of the probe pad 280 is not limited by the undercut, as the size of the probe pad 280 needs to be reduced in order to meet the requirement of continuous minimization of chip size.

In some embodiments, the top side of the packaged semiconductor device 200 in FIG. 2 is covered with a die-bonding film 30. Due to the presence of the redistribution layer 220 and the probe pad 280, the profile of the third insulating layer 270 shows a convex shape at the area corresponding to the redistribution layer 220 and the probe pad 280 (note that the convex profile of the third insulating layer 270 in FIG. 2 is not shown to scale). In some embodiments, the drop height (H2) of the third insulating layer 270 can be limited to less than 3 μm. In contrast, because the packaged semiconductor device 100 in FIG. 1 further includes a fourth insulating layer 190, unlike the packaged semiconductor device 200 in FIG. 2, the drop height (H1) of the fourth insulating layer 190 is increased to about 5 μm, which is greater than the drop height (H2) of the third insulating layer 270 in FIG. 2. Therefore, the packaged semiconductor device 200 is prone to suffer fewer problems, such as cracking, difficulty in heat dissipation, and low reliability.

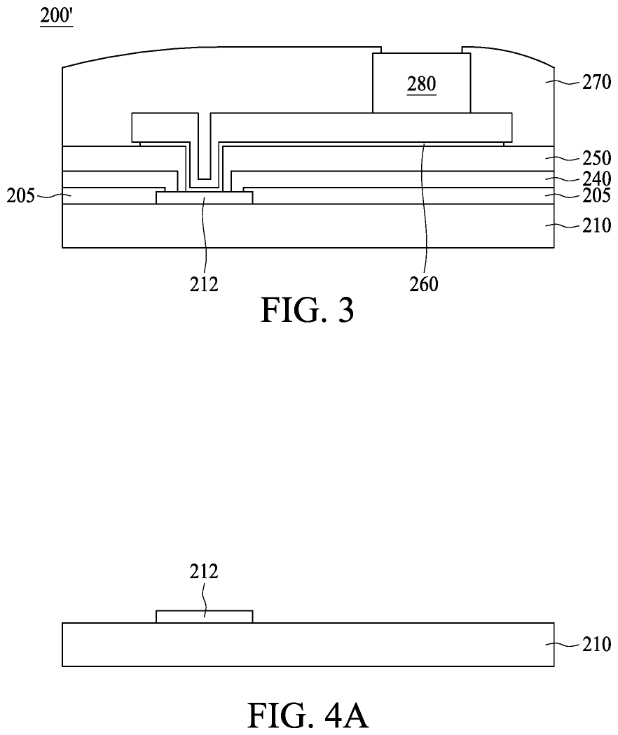

FIG. 3 is a schematic diagram of a packaged semiconductor device 200′ in accordance with some embodiments of the present disclosure. Comparing FIG. 3 with FIG. 2, the packaged semiconductor device 200′ further comprises a protective layer 205 disposed between the first insulating layer 240 and the wafer 210, wherein the protective layer 205 covers a portion of the conductive pad 212. In some embodiments, the protective layer 205 prevents the wafer 210 from being contaminated by the external environment during the preparation of the structure on the wafer 210. In some embodiments, the protective layer 205 covers the sidewall and a portion of the top surface of the conductive pad 212, while the first insulating layer 240 covers the protective layer 205 and a portion of the top surface of the conductive pad 212.

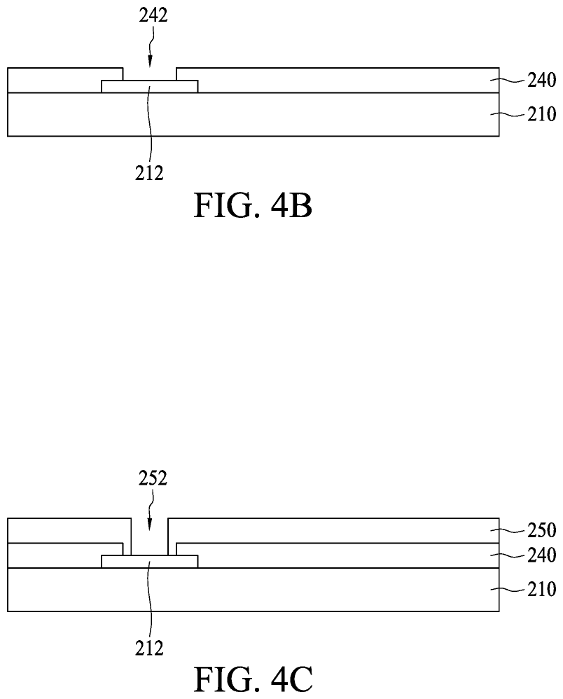

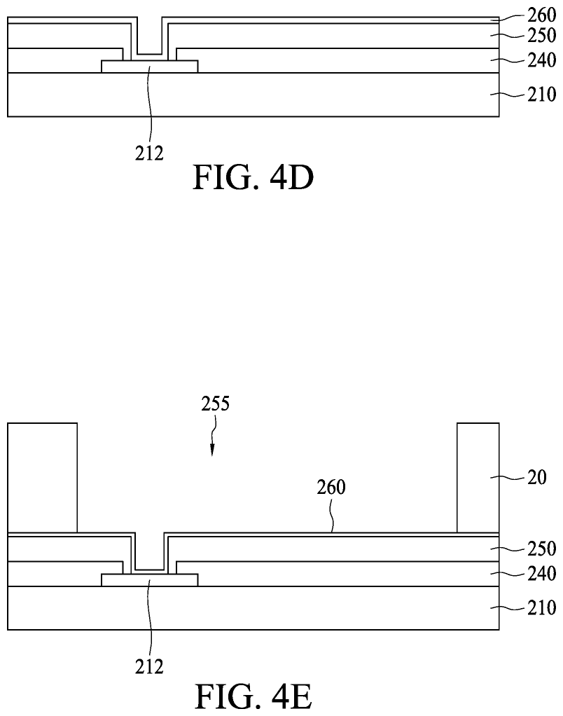

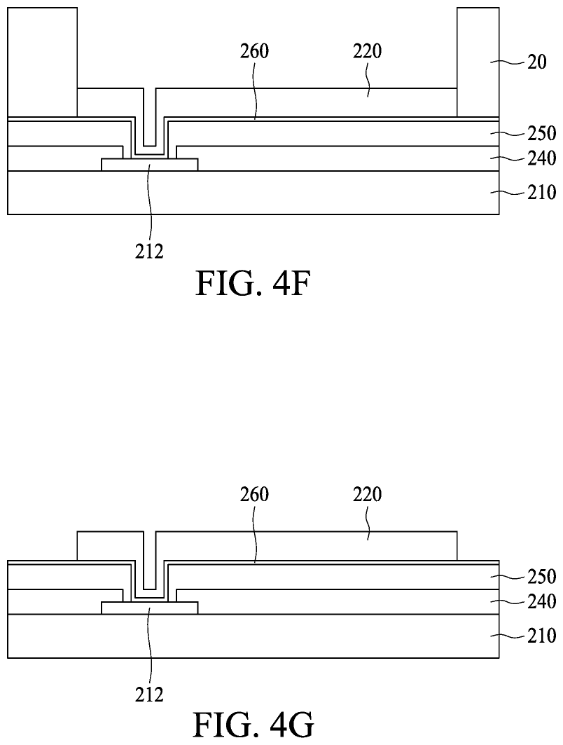

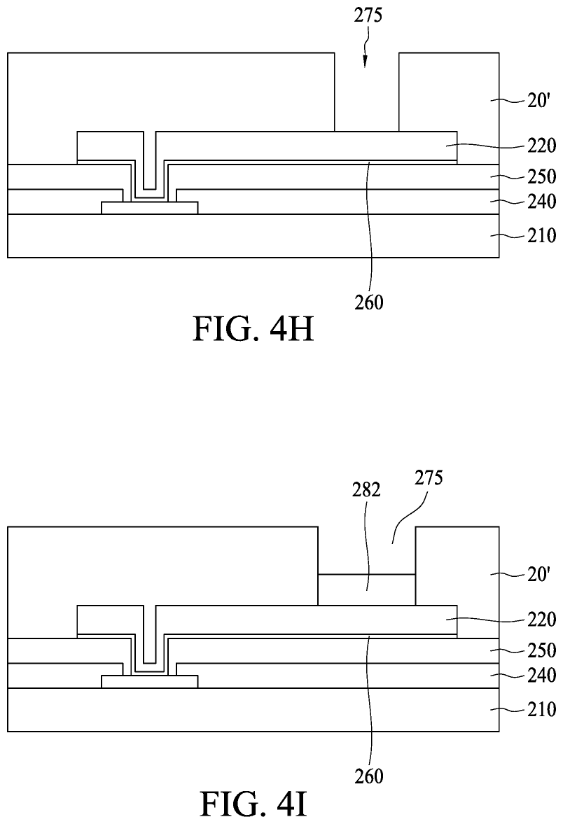

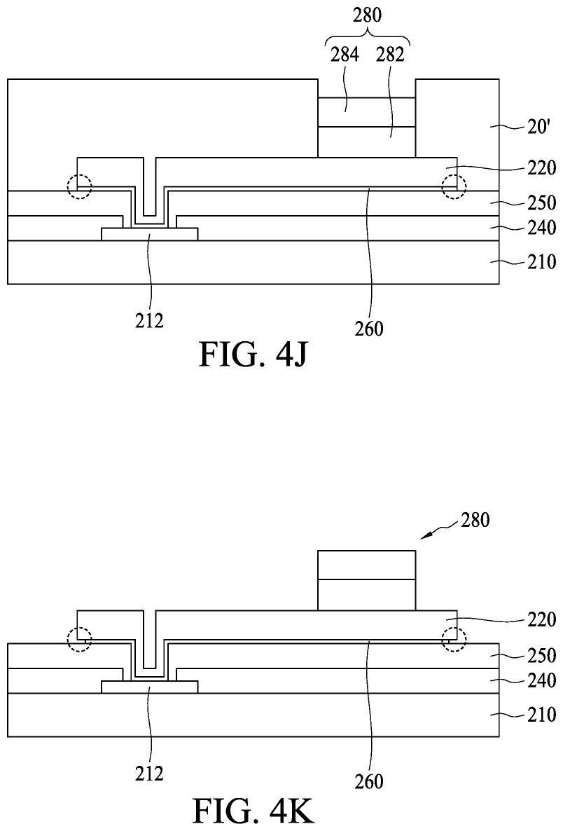

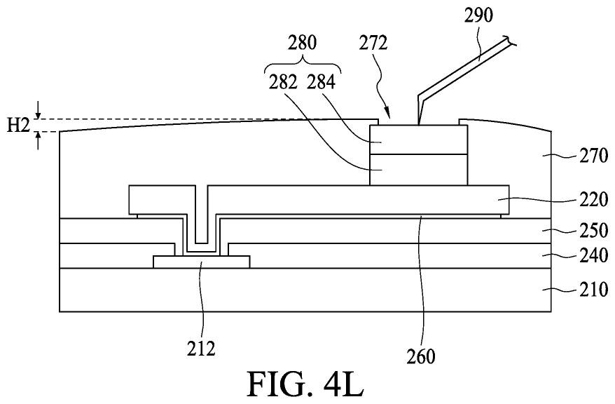

FIG. 4A to FIG. 4L illustrate a method of manufacturing the packaged semiconductor device 200 in FIG. 2 in accordance with some embodiments of the present disclosure. Referring to FIG. 4A, a wafer 210 is provided, and at least one conductive pad 212 is formed on the surface of the wafer 210. In some embodiments, the conductive pad 212 is made of aluminum, but the disclosure is not limited thereto, and the conductive pad 212 may be formed of another metal material having excellent electrical conductivity.

Referring to FIG. 4B, a first insulating layer 240 is formed on the wafer 210, and the first insulating layer 240 includes an opening 242, which exposes a portion of the conductive pad 212. In some embodiments, the material of the first insulating layer 240 is mainly polyimide, but the disclosure is not limited thereto, and the first insulating layer 240 may be formed of another metal material with excellent electrical isolation. In some embodiments, the first insulating layer 240 is formed by chemical vapor deposition (CVD), plasma-enhanced chemical vapor deposition (PECVD), spin coating, or any other suitable process.

Referring to FIG. 4C, a second insulating layer 250 is formed on the first insulating layer 240, and the second insulating layer 250 has an opening 252, which exposes a portion of the conductive pad 212. In some embodiments, the first insulating layer 240 covers the sidewall and a portion of the top surface of the conductive pad 212, while the second insulating layer 250 covers the first insulating layer 240 and a portion of the top surface of the conductive pad 212. The material of the second insulating layer 250 is mainly polyamine, but the disclosure is not limited thereto, and the second insulating layer 250 may be formed of another metal material having excellent electrical isolation.

In some embodiments, the second insulating layer 250 is formed by chemical vapor deposition (CVD), plasma-enhanced chemical vapor deposition (PECVD), spin coating, or any other suitable process.

In some other embodiments, the properties of the second insulating layer 250 and the first insulating layer 240 may be slightly different; for example, the first insulating layer 240 and the second insulating layer 250 may be formed at different locations by different manufacturers. For example, the first insulating layer 240 may be made at the upstream (front-end) manufacturer, while the second insulating layer 250 may be made at the downstream (back-end) manufacturer. Therefore, the first insulating layer 240 and the second insulating layer 250 may be required to be cured at different temperatures. For example, the second insulating layer 250 may be required to be cured below 250° C. In the present embodiment, the first insulating layer 240 and the second insulating layer 250 are manufactured in batches, but those skilled in the art may also choose to simultaneously fabricate the first insulating layer 240 and the second o insulating layer 250.

Referring to FIG. 4D, a conductive film 260 is formed on the second insulating layer 250 and the conductive pad 212, wherein the conductive film 260 is in physical contact with the conductive pads 212. In some embodiments, the material of the conductive film 260 is a Ti/Cu alloy.

Referring to FIG. 4E, a first patterned mask 20 is formed on the conductive film 260 and defines a first region 255 exposing a portion of the conductive film 260. In some embodiments, the first patterned mask 20 is a photoresist layer.

Referring to FIG. 4F, a redistribution layer 220 is formed in the first region 255. In some embodiments, the redistribution layer 220 is electrically plated on the first region 255 using the conductive film 260 as a seeding layer. In some embodiments, the material of the redistribution layer 220 is copper. After the redistribution layer 220 is formed, the first patterned mask 20 is removed by the wet etching process, as shown in FIG. 4G.

Referring to FIG. 4H, a second patterned mask 20′ is formed on the second insulating layer 250. In some embodiments, the second patterned mask 20′ covers the sidewall and a portion of the redistribution layer 220, and defines a second region 275 exposing a portion of the redistribution layer 220, wherein the second patterned mask 20′ is a photoresist layer.

Referring to FIG. 41, a metal block 282 is formed on the second region 275. In some embodiments, the material of the metal block 282 is the same as that of the redistribution layer 220, i.e., copper.

Referring to FIG. 4J, a metal protective layer 284 is formed on the metal block 282. The metal protection layer 284 and the metal block 282 form a probe pad 280. In the present embodiment, the metal protective layer 284 is a nickel-gold layer, i.e., the metal protective layer 284 is formed by stacking a nickel (Ni) layer and a gold (Au) layer.

Referring to FIG. 4K, the second patterned mask 20′ is removed by the wet etching process. Referring to FIG. 4G and FIG. 4K simultaneously, the wet etching process is used to perform the removal of the first patterned mask 20 and the second patterned mask 20′. Because the wet etching process is an isotropic process, an undercut is formed at both ends of the redistribution layer 220, as indicated by the dashed circle in FIG. 4K, showing a region where the undercut phenomenon is likely to occur.

Referring to FIG. 4L, a third insulating layer 270 is formed on the redistribution layer 220 and the second insulating layer 250, and the third insulating layer 270 has an opening 272 exposing the metal protective layer 284. In some embodiments, the third insulating layer 270 covers the sidewall and a portion of the top surface of the metal protective layer 284. In some embodiments, the third insulating layer 270 is formed by chemical vapor deposition (CVD), plasma-enhanced chemical vapor deposition (PECVD), spin coating, or any other suitable process.

In some embodiments, the third insulating layer 270 is mainly made of polyimide. After the manufacturing process of FIGS. 3A through 3L is performed, the packaged semiconductor device 200 in FIG. 2 is completed. After the packaged semiconductor device 200 is completed, a probe 290 on the probe card can contact the probe pad 280 through the opening 272. It can be seen from the above that the metal protective layer (i.e., the nickel-gold layer) 284 is disposed at the uppermost side of the probe pad 280, so that the tip of the probe 290 does not retain any copper after contacting the probe pad 280. As the probe 290 moves to contact an aluminum pad (similar to the conductive pad 212) on the scribe line of the wafer 210, no copper transfer will occur; consequently, the occurrence of an increase in the oxidation rate of the aluminum pad by the copper can be effectively resolved.

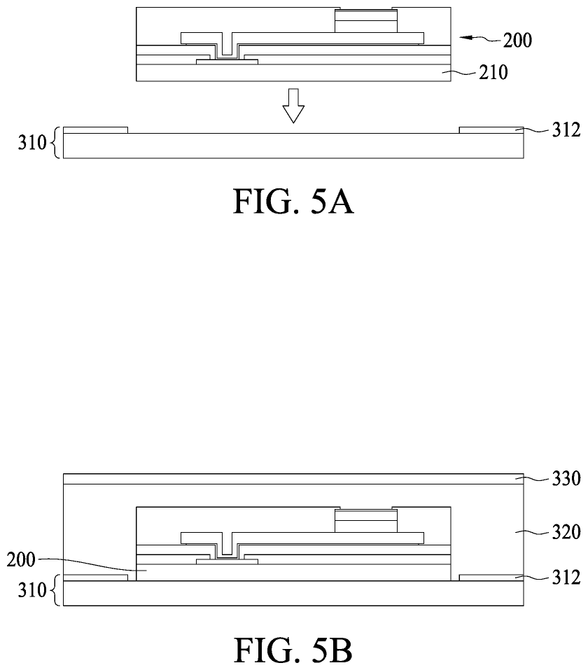

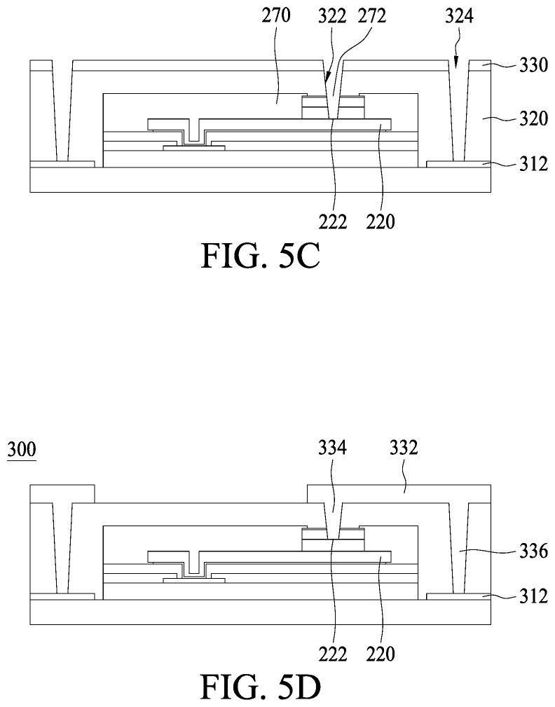

FIG. 5A to FIG. 5D illustrate a manufacturing process for a packaged semiconductor device 300 in accordance with some embodiments of the present disclosure. Referring to FIG. 5A, the wafer 210 of the packaged semiconductor device 200 is mounted onto a substrate 310 having a first wiring layer 312. The material of the first wiring layer 312 is, for example, copper.

In some embodiments, a circuitry having predetermined functionality is fabricated on the substrate 310. In some embodiments, the substrate 310 includes a plurality of conductive lines and a plurality of electronic components, such as transistors and diodes, connected by the conductive lines. In some embodiments, the substrate 310 is a semiconductor substrate. In some embodiments, the substrate 310 is an interposer or chip. In some embodiments, the substrate 310 is a silicon substrate. In some embodiments, the substrate 310 comprises a semiconductor material such as silicon, germanium, gallium, arsenic, or combinations thereof. In some embodiments, the substrate 310 comprises a material such as ceramic, glass, or the like. In some embodiments, the substrate 310 is a glass substrate. In some embodiments, the substrate 310 is quadrilateral, rectangular, square, polygonal, or any other suitable shape.

Referring to FIG. 5B, a fourth insulating layer 320 covers the packaged semiconductor device 200 and the first wiring layer 312. In the present embodiment, the fourth insulating layer 320 functions to fix the packaged semiconductor device 200, and is mainly composed of a prepreg, which is an adhesive sheet obtained by impregnating a resin with an insulating paper, a glass fiber cloth or other fibrous materials.

Next, referring to FIG. 5B, a metal layer 330 is formed on the fourth insulating layer 320, and the material of the metal layer 330 is, for example, copper. In some embodiments, the metal layer 330 may be formed by chemical deposition technology.

Next, referring to FIG. 5C, a fourth opening 322 and a plurality of fifth openings 324 are formed in the fourth insulating layer 320 and the metal layer 330 by means of laser drilling. The fifth opening 324 exposes a portion of the first wiring layer 312. In addition, the fourth opening 322 is in communication with the third opening 272. In some embodiments, the third opening 272 exposes a portion of the redistribution layer 220 of the packaged semiconductor device 200, and the exposed portion can be regarded as a bonding pad 222.

Next, referring to FIG. 5D, a second wiring layer 332 having a first conductive pillar 336 and a second conductive pillar 334 are formed, wherein the second conductive pillar 334 is in contact with the bonding pad 222, while the first conductive pillar 336 is connected to the first wiring layer 312. In some embodiments, the second wiring layer 332 may be formed by techniques, for example, electroplating a layer of copper, and then forming a wiring layer via a patterned process, as known to those skilled in the art.

The present disclosure provides a packaged semiconductor device including a chip having a conductive pad; a first insulating layer disposed on the chip; a second insulating layer disposed on the first insulating layer; a conductive film disposed on the second insulating layer, wherein the conductive film penetrates the second insulating layer and contacts the conductive pad; a redistribution layer disposed on the conductive film; a probe pad disposed on the redistribution layer; and a third insulating layer disposed on the redistribution layer and the second insulating layer; wherein the third insulating layer covers a portion of the probe pad, and there is no undercut at a region between the redistribution layer and the probe pad.

The present disclosure also provides a method for preparing a packaged semiconductor device. The method includes providing a chip having a conductive pad; forming a first insulating layer on the chip, wherein the first insulating layer includes a first opening, and the first opening exposes a portion of the conductive pad; forming a second insulating layer on the first insulating layer; forming a conductive film on the second insulating layer and the conductive pad; forming a first patterned mask on the second insulating layer, wherein the first patterned mask defines a first region exposing a portion of the conductive film; forming a redistribution layer in the first region; forming a second patterned mask on the redistribution layer, wherein the second patterned mask defines a second region exposing a portion of the redistribution layer; for a probe pad in the second region; and forming a third insulating layer on the redistribution layer and the second insulating layer, wherein the third insulating layer includes a second opening, and the second opening exposes a portion of the probe pad.

The scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

1. A packaged semiconductor device, comprising:
a chip comprising a conductive pad;
a first insulating layer disposed on the chip;
a protective layer disposed between the first insulating layer and the chip;
a second insulating layer disposed on the first insulating layer;
a conductive film disposed on the second insulating layer, wherein the conductive film penetrates the second insulating layer and contacts the conductive pad;
a redistribution layer disposed on the conductive film;
a probe pad disposed on the redistribution layer; and
a third insulating layer disposed on the redistribution layer and the second insulating layer;
wherein the protective layer covers a sidewall and a first portion of a top surface of the conductive pad, while the first insulating layer covers the protective layer and a second portion of the top surface of the conductive pad;
wherein the third insulating layer covers a portion of the probe pad, and there is no undercut at a region between the redistribution layer and the probe pad;
wherein a drop height of the third insulating layer is substantially less than 3 μm and more than 0 μm.

2. The packaged semiconductor device of claim 1, further comprising:
a substrate, wherein the chip is disposed on the substrate;
a first wiring layer disposed on the substrate; and
a fourth insulating layer disposed on the third insulating layer and the first wiring layer;
wherein a first conductive pillar penetrates the fourth insulating layer and contacts the first wiring layer.

3. The packaged semiconductor device of claim 1, further comprising:
a substrate, wherein the chip is disposed on the substrate;
a fourth insulating layer disposed on the third insulating layer and a bonding pad which is formed on an exposed portion of the redistribution layer;
a second wiring layer disposed on the fourth insulating layer; and
a first conductive pillar penetrating the fourth insulating layer and contacting the bonding pad.

4. (canceled)

5. The packaged semiconductor device of claim 1, wherein the probe pad comprises a metal block and a metal protective layer.

6. The packaged semiconductor device of claim 5, wherein the metal block is a copper block, and the metal protective layer is a nickel-gold layer.

7. The packaged semiconductor device of claim 1, wherein the conductive film comprises a protrusion protruding towards the chip.

8. The packaged semiconductor device of claim 1, wherein the material of the first insulating layer, the second insulating layer, and the third insulating layer comprises polyimide.

9. The packaged semiconductor device of claim 1, wherein the material of the redistribution layer is copper.

10. The packaged semiconductor device of claim 1, wherein the material of the conductive pad is aluminum.

11. The packaged semiconductor device of claim 1, further comprising a die-bonding film, wherein the die-bonding film covers the third insulating layer.

12. A method for preparing a packaged semiconductor device, comprising:
providing a chip having a conductive pad;
forming a first insulating layer on the chip, wherein the first insulating layer includes a first opening, and the first opening exposes a portion of the conductive pad;
forming a second insulating layer on the first insulating layer;
forming a conductive film on the second insulating layer and the conductive pad;
forming a first patterned mask on the second insulating layer, wherein the first patterned mask defines a first region exposing a portion of the conductive film;
forming a redistribution layer in the first region;
forming a second patterned mask on the redistribution layer, wherein the second patterned mask defines a second region exposing a portion of the redistribution layer;
forming a probe pad in the second region; and
forming a third insulating layer on the redistribution layer and the second insulating layer,
wherein the third insulating layer includes a second opening, and the second opening exposes a portion of the probe pad.

13. The method of claim 12, further comprising:
mounting the chip on a substrate having a first wiring layer thereon;
forming a fourth insulating layer covering the first wiring layer and the third insulating layer;
forming a metal layer covering the fourth insulating layer;
forming a third opening and a fourth opening in the fourth insulating layer and the metal layer, wherein the third opening exposes a portion of the redistribution layer, and the fourth opening exposes a portion of the first wiring layer; forming a second wiring layer having a first conductive pillar and a second conductive pillar, wherein the first conductive pillar is in contact with the redistribution layer, and the second conductive pillar is in contact with the first wiring layer.

14. The method of claim 13, wherein the third opening and the fourth opening are formed by laser drilling.

15. The method of claim 12, wherein the forming of the probe pad comprises forming a nickel-gold layer.

16. The method of claim 12, wherein the material of the first insulating layer, the second insulating layer, and the third insulating layer comprises polyimide.

17. The method of claim 12, wherein the material of the redistribution layer is copper.

18. The method of claim 12, wherein the material of the conductive pad is aluminum.

19. The method of claim 12, further comprising attaching a die-bonding film to the third insulating layer.

20. The method of claim 12, further comprising:
removing the second patterned mask, wherein there is no undercut at a region between the redistribution layer and the probe pad.
